(19) United States
(12) Patent Application Publication
(10) Pub. No.: US 2023/0163042 A1
(43) Pub. Date: May 25, 2023

(54) PACKAGE STRUCTURE AND PACKAGING METHOD

(71) Applicant: Richtek Technology Corporation, Zhubei City (TW)

(72) Inventors: Heng-Chi Huang, Hsinchu (TW); Sheng-Yao Wu, Taoyuan (TW); Min-Shun Lo, Miaoli (TW); Shih-Chieh Lin, Kaohsiung (TW); Yong-Zhong Hu, Hsinchu (TW)

(21) Appl. No.: 17/858,124

(22) Filed: Jul. 6, 2022

Related U.S. Application Data
(60) Provisional application No. 63/282,574, filed on Nov. 23, 2021.

(30) Foreign Application Priority Data
Jan. 21, 2022 (TW) 111102577

(51) Int. Cl. H01L 23/367; H01L 25/065; H01L 23/00; H01L 21/56; H01L 21/48; H01L 23/31; H01L 23/373

(52) U.S. Cl. CPC H01L 23/3675; H01L 25/0655; H01L 24/16; H01L 24/96; H01L 24/97; H01L 21/568; H01L 21/561; H01L 24/11; H01L 21/4882; H01L 23/3121; H01L 23/3735; H01L 2924/30101; H01L 2924/30107; H01L 2224/95001; H01L 24/13; H01L 2224/13147; H01L 2224/13111; H01L 2224/13139; H01L 2224/13116; H01L 2224/11462; H01L 2224/1184; H01L 2224/11849; H01L 2224/16235; H01L 2924/182

(57) ABSTRACT

A package structure includes: a heat dissipation substrate; at least one die, including a signal transmitting side and a heat conduction side, wherein the signal transmitting side and the heat conduction side are two opposite sides on the die, and the heat conduction side is disposed on and in contact with the heat dissipation substrate; plural metal bumps, disposed on the signal transmitting side; and a package material, encapsulating the die, a side of the heat dissipation substrate in contact with the die, and the metal bumps, wherein a portion of each metal bump is exposed to an outside of the package material.

### CROSS REFERENCE

The present invention claims priority to provisional application 63/282,574 filed on Nov. 23, 2021, and TW 111102577 filed on Jan. 21, 2022.

### BACKGROUND OF THE INVENTION

### Field of Invention

The present invention relates to a package structure, especially a package structure wherein a die is not connected to a lead frame so that the parasitic resistance and inductance are reduced, and as such the lead frame can even be omitted.

### Description of Related Art

FIG. 1 shows a package structure 100 in a quad flat no lead (“QFN” hereinafter) package is shown, which is one typical packaging method to encapsulate a die 101. This packaging method uses a lead frame 102 as a carrier structure, wherein a die 101 is attached to the lead frame 102 by soldering. The lead frame 102 and the die 101 thereon are encapsulated by a package material (or molding compound) 104; and then the encapsulated die 101 and lead frame 102 are cut into an individual package unit, that is, plural package units are manufactured concurrently and each of which includes the die 101 and the lead frame 102. The die 101 in the QFN package communicate with its outside through the exposed portions of the lead frame 102.

There is a problem that the QFN package needs to face. The lead frame 102 may cause high parasitic resistance and high parasitic inductance during transmitting signals. Referring to FIG. 2, when the circuit starts operating, a ringing effect occurs due to the parasitic resistance and inductance of the lead frame 102, and this can last for quite a long time to result in a delay in signal transmission. The parasitic inductance will increase the impedance even more significantly when transmitting high frequency signals, and the ringing effect becomes even more noticeable under a high current condition.

Referring to FIG. 3, in order to overcome this problem, a prior approach is to do circuit optimization by circuit analysis software, to straighten the right-angle turns in the lead frame for shortening the signal communication length, so as to reduce the parasitic resistance and inductance thereof.

Regarding heat dissipation in the package structure, a typical prior art approach is to dispose an additional heat dissipation material on the die on the lead frame to enhance the heat dissipation capability. For instance, FIG. 4 shows the package structure 10 of U.S. Pat. No. 7,812,437; FIG. 5 shows the package structure 20 of U.S. Pat. No. 7,164,210; and FIG. 6 shows the package structure 30 of U.S. Pat. No. 7,560,309. In these patents, the dies 11, 21, and 31 are disposed on the lead frames 12, 22, and 32, which are encapsulated by the package materials 14, 24, and 34, correspondingly; and the heat dissipation materials 15, 25, and 35 are disposed on the dies 11, 21, and 31, correspondingly. In manufacturing the package structures 10, 20, and 30, the heat dissipation materials 15, 25, and 35 are disposed after the dies 11, 21, and 31 are disposed on the lead frames 12, 22, and 32. These disposition processes are complicated and any error during these processes can cause the cooling effect of dies 11, 21, and 31 to be downgraded. Besides, the problem of the aforementioned high parasitic resistance and inductance still remains and is not solved by these prior arts.

In view of the aforementioned drawback in the prior arts, the present invention provides a package structure wherein the lead frame is omitted to significantly reduce the parasitic resistance and inductance caused by the lead frame, and further to provide a high heat dissipation efficiency in the package structure.

### SUMMARY OF THE INVENTION

In one perspective, the present invention provides a package structure, which can greatly reduce the parasitic resistance and inductance as compared to the prior art, and at the same time have the performance of high heat dissipation efficiency. The package structure of the present invention includes: a heat dissipation substrate; at least one die, each die including a signal transmitting side and a heat conduction side, wherein the signal transmitting side and the heat conduction side are two opposite side to each other, and the heat conduction side is disposed on and in contact with the heat dissipation substrate; a plurality of metal bumps, disposed on the signal transmitting side; and a package material, encapsulating the die, a side of the heat dissipation substrate in contact with the die, and the metal bumps, wherein a portion of each metal bump is exposed outside the package material.

In one embodiment, the signal transmitting side has no signal connection with the lead frame.

In one embodiment, the heat dissipation substrate is made of a high thermal conductive material.

In one embodiment, the heat dissipation substrate has aside which is exposed to the outside of the package structure, and this exposed side has a planar shape, a wavy surface, or has a matrix of one or more geometric shapes.

In one embodiment, a heat dissipation path between the die and the outside of the package structure is formed through the heat conduction side of the die and the heat dissipation substrate, to transfer a heat energy generated by the die to the outside of the package structure.

In one embodiment, the metal bumps are electrically connected to an external circuit board or a redistribution layer.

In one embodiment, the metal bumps are fabricated by an electroplating process or a ball mounting process. The material of the metal bumps includes a metal, an alloy, or a composite material structure.

In one embodiment, the package structure includes a plurality of dies, wherein the metal bumps are disposed on the signal transmitting sides of the dies, and the heat conduction sides of the dies are disposed on the heat dissipation substrate.

In one embodiment, the package structure further includes a plurality of routing lines disposed on the package material for transmitting signals between the metal bumps. The package structure further includes a stack package layer to encapsulate the routing lines and the package material.

In one perspective, the present invention provides a package method, which includes: providing at least one die, each die including a signal transmitting side and a heat conduction side, wherein the signal transmitting side and the heat conduction side are two opposite side to each other; disposing a plurality of metal bumps on the signal transmitting side; disposing a heat dissipation substrate under and in contact with the heat conduction side; providing a package material to encapsulate the at least one die on the heat dissipation substrate and to encapsulate the metal bumps; and after the step of providing a package material to encapsulate the at least one die on the heat dissipation substrate and to encapsulate the metal bumps, cutting to separate the at least one die, the heat dissipation substrate and the metal bumps from other portions to form at least one package unit, wherein each package unit includes the at least one die, the metal bumps, a post-cut heat dissipation substrate, and a post-cut package material.

In one embodiment, the aforementioned at least one die includes: a die, a plurality of dies, or a plurality of dies on a wafer.

In one embodiment, the at least one die includes a plurality of dies, wherein the metal bumps are disposed in the signal transmitting side of each die, and the heat conduction side of each die is disposed on the heat dissipation substrate; wherein the package method further includes: disposing a plurality of routing lines on the package material to respectively connect the metal bumps; and disposing a stack package layer to encapsulate the routing lines on the package material.

In one embodiment, after the step of providing a package material to encapsulate the at least one die on the heat dissipation substrate and to encapsulate the metal bumps, the package method further includes: grinding the package material and the metal bumps; and performing a reflow step to recover tops of the metal bumps.

In one embodiment, the heat dissipation substrate is disposed on a carrier layer, and the package method further includes: after each package unit is formed, removing the package unit from the carrier layer.

The objectives, technical details, features, and effects of the present invention will be better understood with regard to the detailed description of the embodiments below, with reference to the attached drawings.

### BRIEF DESCRIPTION OF THE DRAWINGS

FIGS. 1 to 6 show several prior art package structures.

FIG. 7 shows a package structure according to one embodiment of the present invention.

FIGS. 8 and 9A to 9E respectively show heat dissipation substrates according to several embodiments of the present invention.

FIGS. 10A to 10C show dies and metal bumps according to several embodiments of the present invention.

FIG. 11 shows a package structure according to one embodiment of the present invention.

FIGS. 12A to 12D show steps in the package method according to one embodiment of the present invention.

FIGS. 13A to 13E show steps in the package method according to one embodiment of the present invention.

FIGS. 14A to 14F show steps of the package method according to one embodiment of the present invention.

FIG. 15 shows a comparison table of electrical characteristics between the prior art and the present invention.

FIG. 16 shows a thermal resistance comparison between the prior art and the present invention.

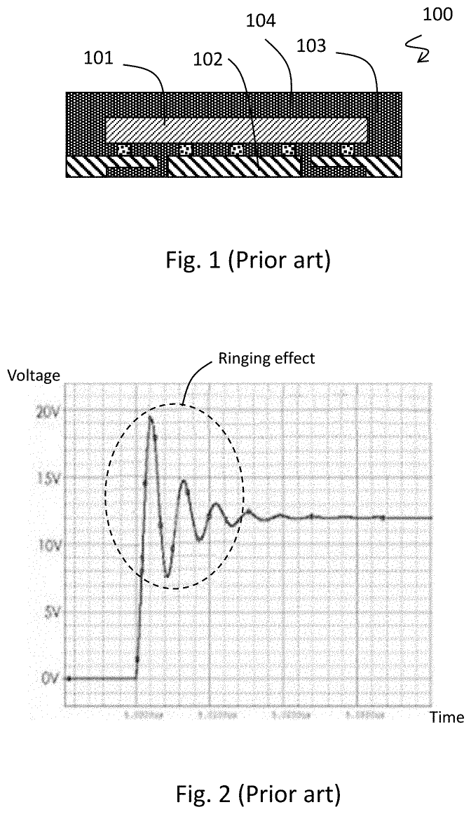

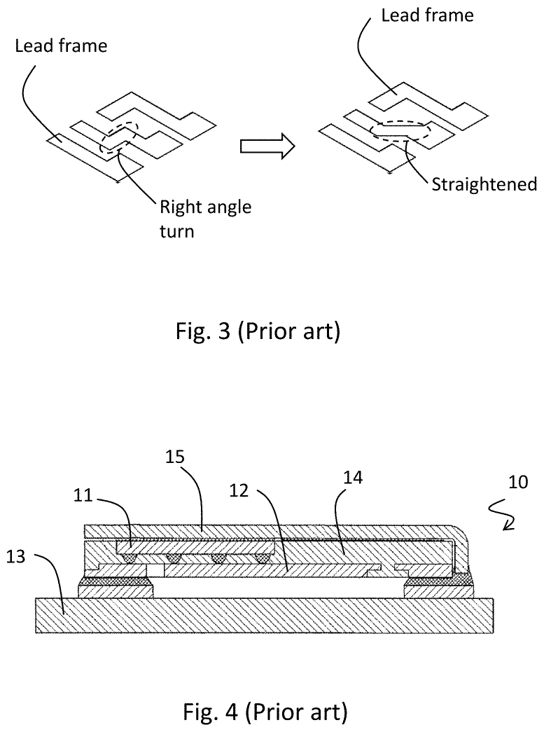

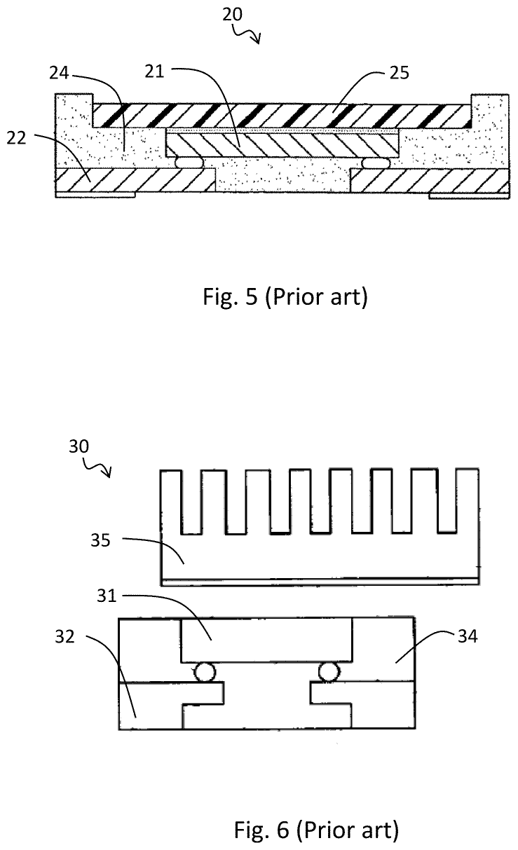

### DESCRIPTION OF THE PREFERRED EMBODIMENTS

The drawings as referred to throughout the description of the present invention are for illustration only, to show the interrelations between the components or units, but not drawn according to actual scale of sizes.

Compared with the prior packaging technology, the present invention omits the lead frame, so that the package structure has lower parasitic resistance and inductance. The heat dissipation substrate provides both functions for disposing the die and for heat dissipation, so that the package structure and the manufacturing process are simplified while the signal transmission efficiency is improved.

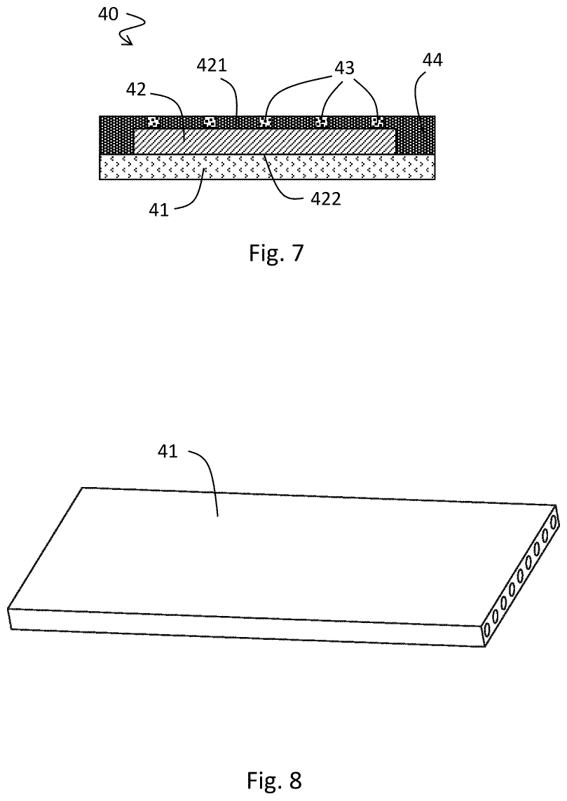

FIG. 7 shows a package structure 40 according to an aspect of the present invention, the package structure 40 including: a heat dissipation substrate 41, at least one die 42, a plurality of metal bumps 43 and a package material 44. Each die 42 includes a signal transmitting side 421 and a heat conduction side 422, wherein the signal output side 421 and the heat conduction side 422 are opposite sides to each other on the die (for example, in FIG. 7, the signal transmitting side 421 and the heat conduction side 422 are the top side and the bottom side of the die 42, respectively), and the heat conduction side 422 are disposed on the heat dissipation substrate 41 (different from the prior art wherein the die is disposed on the lead frame, the die 42 of the present invention is disposed on the heat dissipation substrate 41 in an up-side-down fashion). The plurality of metal bumps 43 are disposed on the signal transmitting side 421, whereby the die 42 in the package structure 40 can transmit and receive signals through the metal bumps 43 in communication with outside of the package structure 40. The package material 44 encapsulates the die 42, a side of the heat dissipation substrate 41 which is connected to the die 42, and the metal bumps 43. One side of each metal bumps 43 is exposed to the outside of the package material 41. FIG. 7 shows a package structure including one die. According to the present invention, a package structure can include multiple dies, which will be illustrated in other embodiments.

In the prior art, the lead frame needs to provide both functions of signal transmission and heat dissipation, that is, the signal transmitting side and the heat conduction side of the die are on the same side. In the present invention, the signal transmitting side 421 and the heat conduction side 422 of the die 42, are not on the same side of the die 42, but on opposite sides to each other. The signal transmitting side 421 has no signal connection with the lead frame. In some embodiments of the present invention, the package structure does not include the lead frame.

In one embodiment, the heat dissipation substrate 41 is made of a high thermal conductive material. The material of the heat dissipation substrate 41 can include a metal (for example, copper or aluminum), a ceramic material, an alloy (for example, aluminum copper alloy), or a composite structure (for example, nickel-coated copper, or graphene-coated copper plate).

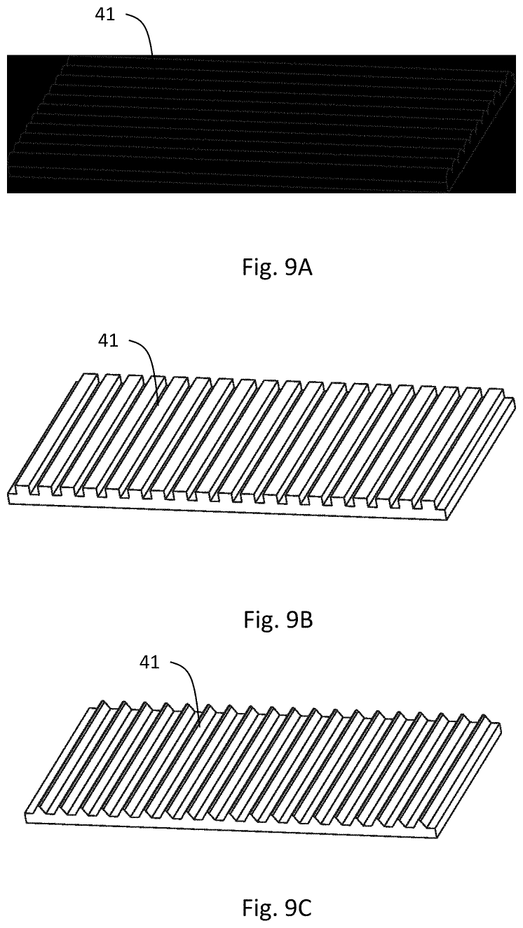

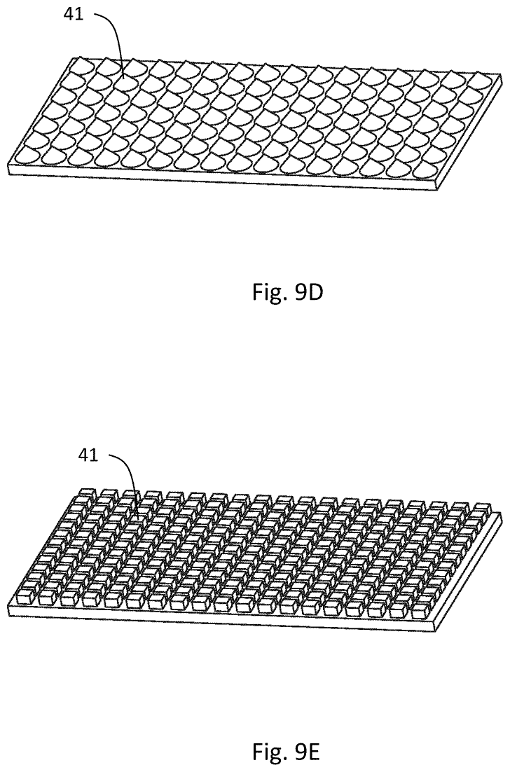

In some embodiments, a side of the heat dissipation substrate 41 exposed to the outside of the package structure 40 (that is, the side opposite to the side of the heat dissipation substrate 41 connected to the die 42) is of a planar shape (for example: plane with a solid body, or plane with hollow pipes under (FIG. 8)); a wavy surface; or a matrix of specific geometric shapes (geometric shapes such as: extending arc shape (FIG. 9A), extending square shape (FIG. 9B), extending triangle shape (FIG. 9C), conical protrusion shape (FIG. 9D), square protrusion shape (FIG. 9E), cylinder shape, etc.). These surface designs of the heat dissipation substrate can increase the contact surface of the heat dissipation substrate 41 to the outside, to improve the heat dissipation performance.

In one embodiment, a heat dissipation path between the die 42 and the outside of the package structure 40 is formed through the heat dissipation substrate 41 and the heat conduction side 422 of the die 42, to transfer the heat energy generated by the die 42 to the outside of the package structure 40. Thus, besides reducing the parasitic resistance and inductance, the package structure 40 according to the present invention further has a better heat dissipation effect over the prior art package structure with lead frame. The material, thickness or shape of the heat dissipation substrate 41 can be flexibly determined to achieve a much better heat conduction and heat transfer efficiency, as compared to the prior art lead frame technology which is relatively more limited under the manufacturing requirements.

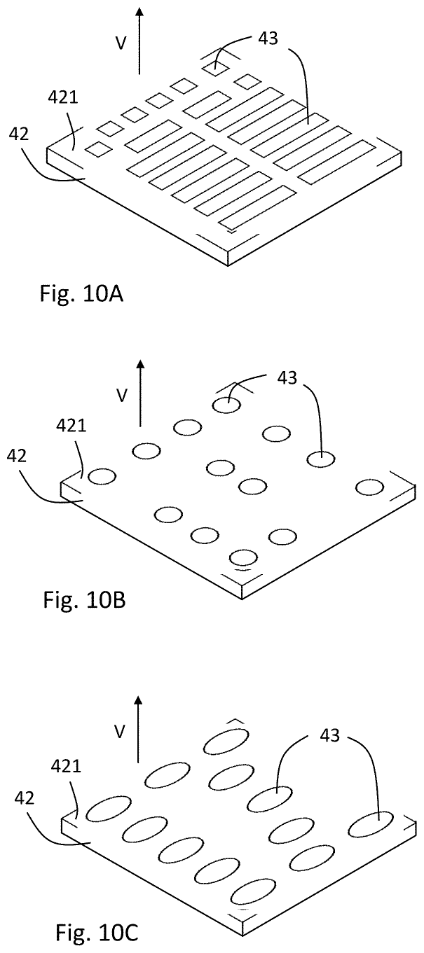

In embodiments as shown in FIGS. 10A, 10B, and 10C, in a projection of the signal transmitting side 421 of the die 42 along a vertical direction V, the metal bumps 43 may include various geometric shapes, such as: square (FIG. 10A), circle (FIG. 10B), ellipse (FIG. 10C), polygon, etc., which can be determined according to manufacturing or signal wiring requirements.

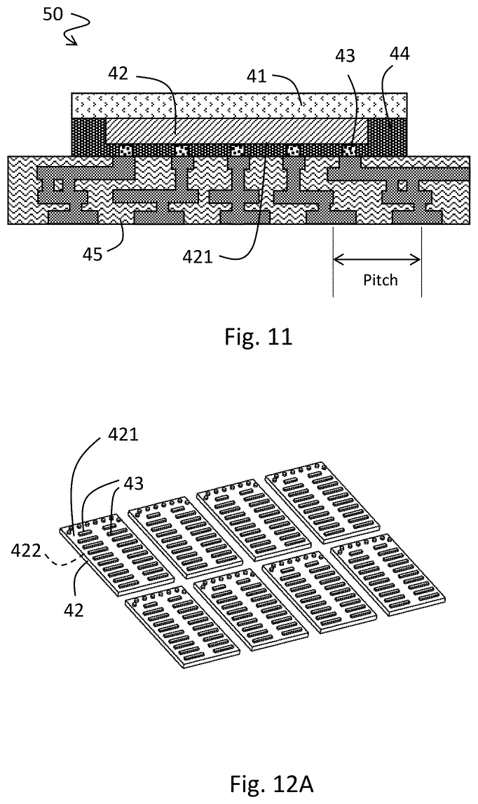

In one embodiment as shown by the package structure 50 of FIG. 11, the metal bumps 43 can be electrically connected to an external circuit board 45 (or a flexible circuit board), or a redistribution layer. When the metal bumps 43 are arranged in a dense layout, a redistribution layer or an external circuit board can be added to adjust the pitch of the layout for better signal contacts with external circuitry.

In embodiments as shown in FIGS. 7 and 11, a package material 44 fills the gaps or space between the metal bumps 43. From one perspective, at least a portion of the signal transmitting side 421 between the metal bumps 43 is filled with the package material 44.

In one embodiment, the metal bump 43 can be fabricated on the signal transmitting side 421 by an electroplating process or a ball mounting process. The material of the metal bumps 43 can include: metal (for example, tin, or copper), alloys (for example, tin silver alloy, or tin lead alloy), or composite structure (for example, copper in combination with tin silver alloy).

The package structure of the present invention can be applied to modify the prior art QFN package structure, and other prior art package structures. The aforementioned QFN package is one example for this modification, and the application of the present invention is not limited to the QFN package; any package structure with lead frame can be modified according to the present invention to omit the lead frame, and to use the heat dissipation substrate as proposed by the present invention.

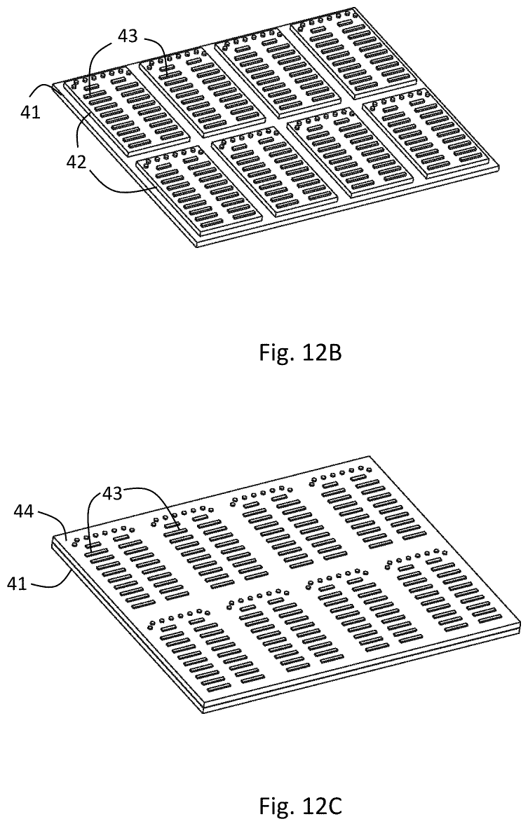

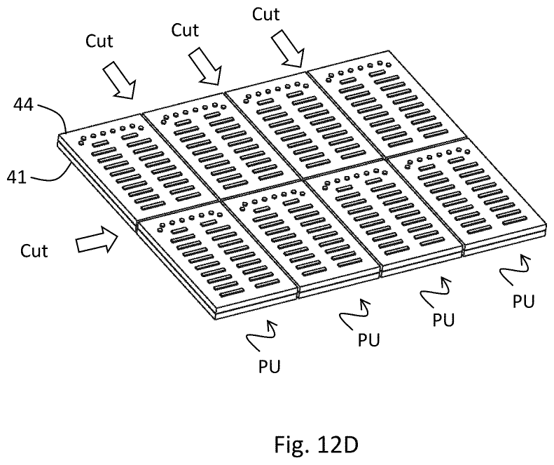

In one perspective, FIGS. 12A to 12D provide a package method, which includes: providing at least one die 42 (FIG. 12A, wherein eight dies are shown as an example), each die 42 including a signal transmitting side 421 and a heat conduction side 422, and disposing a plurality of metal bumps 43 on the signal transmitting side 421, wherein the metal bumps 43 can be one same shape or multiple different shapes; disposing a heat dissipation substrate 41 on (or under, from the illustration view of the drawing) and connected to the heat conduction side 422 of the die 42 (FIG. 12B); providing a package material 44 to encapsulate the at least one die 42 on the heat dissipation substrate 41 and to encapsulate the metal bumps 43, wherein one side of each of the metal bumps 43 is exposed outside the package material 44 (FIG. 12C); and cutting to separate the at least one die 42, the metal bumps 43 and the heat dissipation substrate 41 (arrows illustrate the cutting after encapsulating the package material 44, FIG. 12D) from other portions to form at least one package unit PU (FIG. 12D shows an example of cutting to form eight package units PU). Each package unit PU includes the die 42, the metal bumps 43, a post-cut heat dissipation substrate, and a post-cut package material.

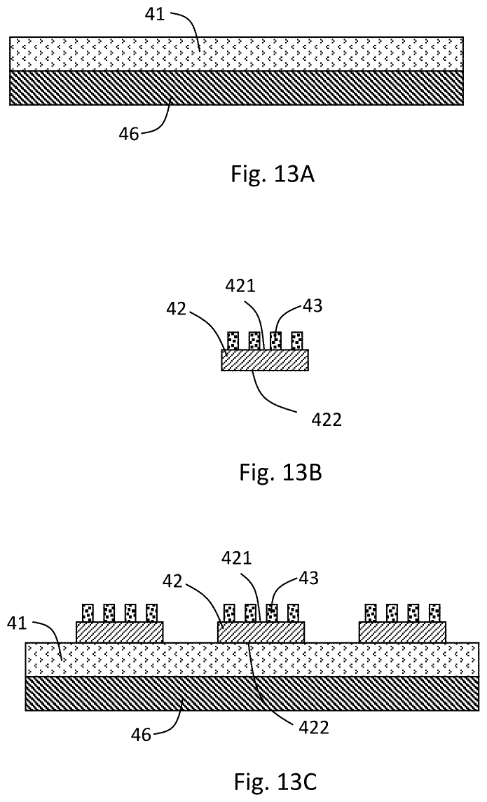

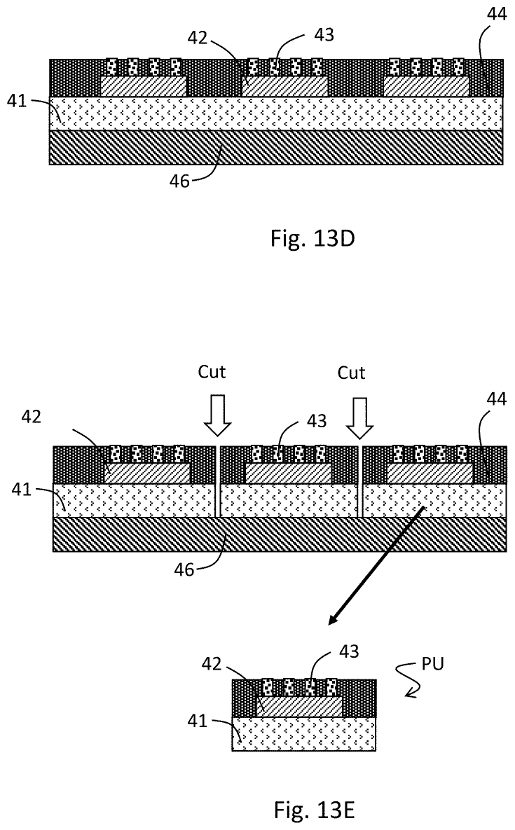

In one embodiment, when the heat dissipation substrate 41 is a flexible material, the heat dissipation substrate 41 can be pre-disposed on a carrier layer 46 (FIG. 13A). As shown in FIGS. 13B to 13D, the steps of the package method provided by the present invention further include: providing at least one die 42 (FIG. 13B), each die 42 including a signal transmitting side 421 and a heat conduction side 422, and disposing a plurality of metal bumps 43 on the signal transmitting side 421, wherein the metal bumps 43 can be one same shapes or multiple different shapes; disposing a heat dissipation substrate 41 on (or under, from the illustration view of the drawing) and connected to the heat conduction side 422 of the die 42 (FIG. 13C); providing a package material 44 to encapsulate the at least one die 42 on the heat dissipation substrate 41 and to encapsulate the metal bumps 43 (FIG. 13D); and after encapsulating the at least one die 42, cutting to separate (arrows illustrate the cutting) the metal bumps 43 and the heat dissipation substrate 41 from other portions to form at least one package unit PU, and removing each package unit PU from the carrier layer 46 (FIG. 13E). Each package unit PU includes the die 42, the metal bumps 43, a post-cut heat dissipation substrate, and a post-cut package material.

In one embodiment, the at least one die in the package method can include: a die, a plurality of dies, or a plurality of dies on a wafer.

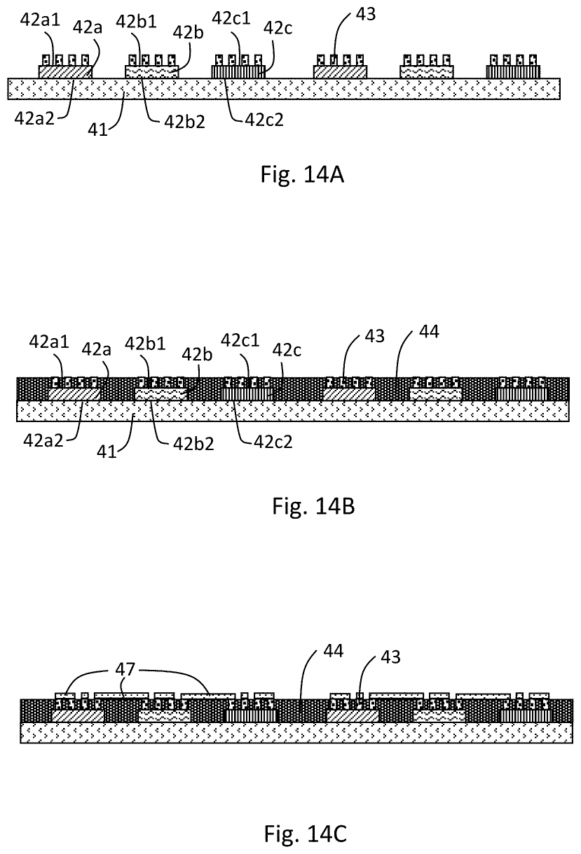

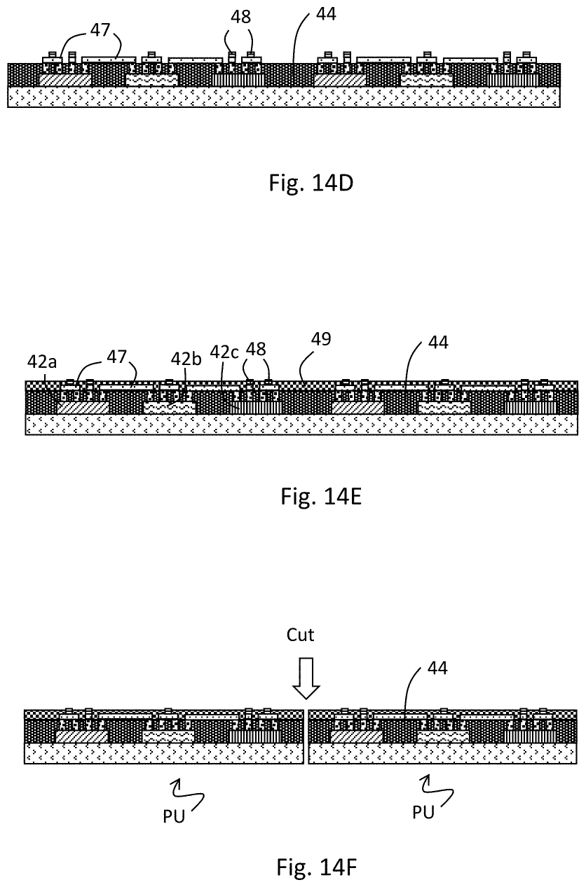

In one embodiment, one package unit PU can include multiple dies. In one embodiment as shown in FIGS. 14A to 14F, the steps of the package method provided by the present invention include: providing a plurality of dies 42a, 42b, and 42c, and disposing a plurality of metal bumps 43 on the signal transmitting sides 42a1, 42b1, and 42c1 of the dies 42a, 42b, and 42c, respectively, wherein the heat conduction sides 42a2, 42b2 and 42c2 of the dies 42a, 42b, and 42c are disposed on and in contact with the heat dissipation substrate 41 (FIG. 14A); providing a package material 44 to encapsulate the dies 42a, 42b, and 42c on the heat dissipation substrate 41 and to encapsulate the metal bumps 43 (FIG. 14B); disposing a plurality of routing lines 47 on the package material 44, to respectively connect the metal bumps 43 (FIG. 14C); disposing a plurality of metal stack bumps 48 on the routing lines 47, to electrically connect the routing lines 47 and/or to electrically connect the metal bumps 43 (FIG. 14D); disposing a stack package layer 49 to encapsulate the routing lines 47 and the metal stack bump 48 on the package material 44 (FIG. 14E); and cutting to separate the dies 42a, 42b, 42c, the metal bumps 43, the metal stack bumps 48, and the heat dissipation substrate 41 (arrows illustrate the cutting) encapsulated by the package material 44 and the stack package layer 49 from other portions, to form plural package units PU. In this embodiment, each package unit PU includes multiple different dies 42a, 42b, and 42c (FIG. 14F), wherein the routing lines provide signal connections among the dies 42a, 42b, and 42c.

In one embodiment, after the above-mentioned step of encapsulating the die 42a, 42b, 42c and the metal bumps 43 (or after the step of encapsulating the stack package layer 49 and the metal stack bumps 48), the exposed surface on the package structure may need to be planarized by grinding (or polishing). However, this grinding or polishing step may damage the metal bumps 43 (or the metal stack bumps 48). Therefore, after the aforementioned step of encapsulating the dies 42a, 42b, 42c and the metal bumps 48 (or after the step of encapsulating the stack package layer 49 and the metal stack bumps 48), when a step of grinding the package material 44 and the metal bumps 43 (or grinding the stack package layer 49 with metal stack bumps 48) is required, after the grinding step, a reflow step can be performed to recover the tops of the metal bumps 43 (or the tops of metal stack bumps 48), wherein the tops of the metal bumps or of the metal stack bumps 4843 are tops of exposed to the outside of the package material 44.

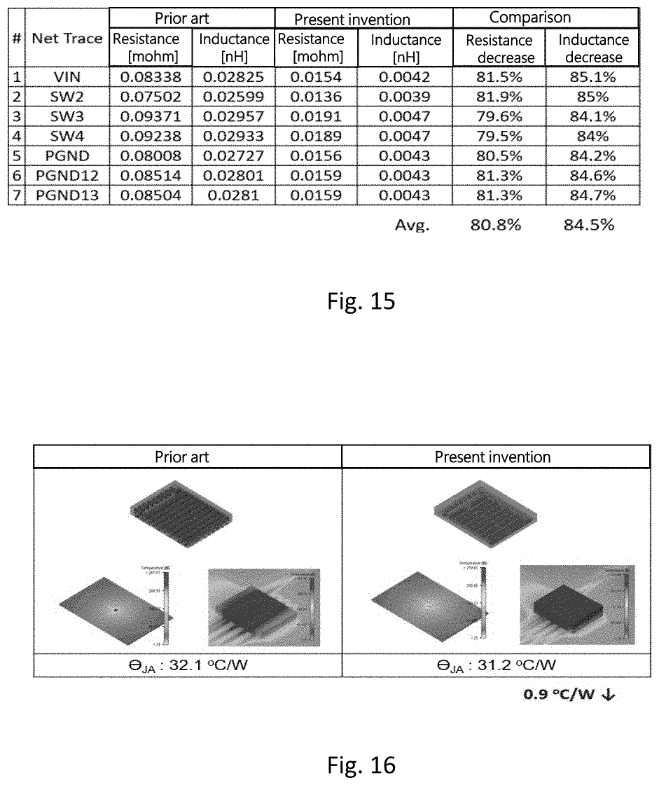

FIG. 15 shows a comparison table of electrical characteristics between the prior art and the present invention (the present invention omitting the lead frame). The comparison results show that the parasitic resistance and inductance of the package structure in the present invention are in average 80% lower than that of the QFN package of the prior art, showing that the performance of the present invention is much improved over the prior art. Besides, FIG. 16 shows a thermal resistance comparison between the prior art and the present invention. The comparison shows that the thermal resistance in the package of the present invention can be 0.9° C./W lower than the package thermal resistance of the prior art QFN package.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. For example, the package structure is provided with a different number of dies to the drawings, or the components are placed in a different sequence, or the shapes of the components are different from the drawings, etc. In view of the foregoing, the spirit of the present invention should cover all such and other modifications and variations, which should be interpreted to fall within the scope of the following claims and their equivalents.

What is claimed is:

1. A package structure, including:
a heat dissipation substrate;
at least one die, each die including a signal transmitting side and a heat conduction side, wherein the signal transmitting side and the heat conduction side are two opposite side to each other, and the heat conduction side is disposed on and in contact with the heat dissipation substrate;
a plurality of metal bumps, disposed on the signal transmitting side; and
a package material, encapsulating the die, a side of the heat dissipation substrate in contact with the die, and the metal bumps, wherein a portion of each metal bump is exposed outside the package material.

2. The package structure according to claim 1, wherein the signal transmitting side has no signal connection with a lead frame.

3. The package structure according to claim 1, wherein the heat dissipation substrate is made of a high thermal conductive material.

4. The package structure according to claim 3, wherein the material of the heat dissipation substrate includes a metal, an alloy, or a composite material structure.

5. The package structure according to claim 3, wherein the heat dissipation substrate has a side which is exposed to the outside of the package structure, and this exposed side has a planar shape, a wavy surface, or has a matrix of one or more geometric shapes.

6. The package structure according to claim 3, wherein a heat dissipation path between the die and the outside of the package structure is formed through the heat conduction side of the die and the heat dissipation substrate, to transfer a heat energy generated by the die to the outside of the package structure.

7. The package structure according to claim 1, wherein the metal bumps are electrically connected to an external circuit board or a redistribution layer.

8. The package structure of claim 1, wherein the metal bumps are manufactured by an electroplating process or a ball mounting process.

9. The package structure according to claim 1, wherein the material of the metal bumps includes a metal, an alloy, or a composite material structure.

10. The package structure according to claim 1, wherein the at least one die includes a plurality of dies, wherein the metal bumps are disposed on the signal transmitting side of each die, and the heat conduction side of each die is disposed on the heat dissipation substrate.

11. The package structure described in claim 10, further including a plurality of routing lines on the package material to connect the metal bumps for transmitting signals, wherein the package structure further includes a stack package layer to encapsulate the routing lines and the package material.

12. A package method, including:
providing at least one die, each die including a signal transmitting side and a heat conduction side, wherein the signal transmitting side and the heat conduction side are two opposite side to each other;
disposing a plurality of metal bumps on the signal transmitting side;
disposing a heat dissipation substrate under and in contact with the heat conduction side;
providing a package material to encapsulate the at least one die on the heat dissipation substrate and to encapsulate the metal bumps; and
after the step of providing a package material to encapsulate the at least one die on the heat dissipation substrate and to encapsulate the metal bumps, cutting to separate the at least one die, the heat dissipation substrate and the metal bumps from other portions to form at least one package unit, wherein each package unit includes the at least one die, the metal bumps, a post-cut heat dissipation substrate, and a post-cut package material.

13. The package method of claim 12, wherein the at least one die includes: a die, a plurality of dies, or a plurality of dies on a wafer.

14. The package method according to claim 12, wherein the at least one die includes a plurality of dies, wherein the metal bumps are disposed in the signal transmitting side of each die, and the heat conduction side of each die is disposed on the heat dissipation substrate; wherein the package method further includes: disposing a plurality of routing lines on the package material to respectively connect the metal bumps; and disposing a stack package layer to encapsulate the routing lines on the package material.

15. The package method according to claim 12, wherein after the step of providing a package material to encapsulate the at least one die on the heat dissipation substrate and to encapsulate the metal bumps, the package method further includes: grinding the package material and the metal bumps; and performing a reflow step to recover tops of the metal bumps.

16. The package method according to claim 12, wherein the heat dissipation substrate is disposed on a carrier layer, and the package method further includes: after each package unit is formed, removing the package unit from the carrier layer.
